(19) United States
(12) Patent Application Publication
(10) Pub. No.: US 2012/0057281 A1
(43) Pub. Date: Mar. 8, 2012

(54) MOBILE SOLAR ENERGY SYSTEM

(76) Inventor: Chia-Yu Lee, Taipei City (TW)

(21) Appl. No.: 13/221,362

(22) Filed: Aug. 30, 2011

(30) Foreign Application Priority Data
Sep. 3, 2010 (TW) 099217145

(51) Int. Cl. H05K 7/00

(52) U.S. Cl. 361/679.01

(57) ABSTRACT

A mobile solar energy system is disclosed, which comprises a case and a solar energy device received in a chamber of the case. A cover is disposed above the chamber. The solar energy device comprises solar panels and a controlling device, and a plurality of solar modules are disposed on the solar panels. A battery module electrically connected to the controlling device is connected to the solar panels so that, when the sunlight propagates through the cover to the solar panels, the solar energy can be transformed into electric energy for charging the battery module. Thus, the solar energy device can be put into a standard case and transported in the case by a means of transportation, which makes it convenient to move with improved mobility; and a pollution-free and noise-free power supply can be provided by the solar energy device, which makes it more competitive in the market.

This application claims the priority benefit of Taiwan patent application number 100103836 file on Feb. 1, 2011.

### BACKGROUND OF THE INVENTION

1. Field of the Invention

The present invention relates to a mobile solar energy system, and more particularly, to a mobile solar energy system that has a solar energy device received inside a case so that, when the sunlight propagates through the cover disposed above the case onto solar panels, the solar energy can be transformed into electric energy for charging a battery module and that allows the case to be transported by a means of transportation conveniently with improved mobility.

2. Description of the Related Art

Nowadays, creating green dwelling environments has become an idea promoted by various countries. However, in the highly civilized world, people's activities (e.g., all means of transportation that are powered by fossil oil emit carbon dioxide (CO₂)) have caused the content of carbon dioxide in the air to rise continuously. This makes the greenhouse effect more and more serious and leads to global warming and abnormal climates. Therefore, almost all countries worldwide are now making great efforts to develop alternative energy resources that can replace the fossil oil.

Furthermore, common alternative energy resources primarily include biomass energy resources, wind power generation and solar power generation, among which the solar power generation has received the most attention. Because the solar energy is inexhaustible and easy to get and does not emit harmful substances, solar energy related industries have developed rapidly.

It is difficult for the conventional utility power to satisfy the demands for power supply in outdoor environments (e.g., in the country, islands, mountainous areas, suburb areas, outdoor environments in urban areas or other open environments), especially in case of a power failure, in a stricken area, or in other scenarios where a power supply cannot be obtained readily such as at the beach, a large-scale outdoor concert, a commercial exhibition or a mobile performance. In order to ensure stable supply of the electric power, a number of dedicated large-scale outdoor power generators are usually used as an outdoor power supply or cables are laid from a long distance for connection with the utility power. However, in consideration of shortage of the utility power and the frequent changes in the weather, sometimes it is impossible to ensure the reliability in power supplying; moreover, electromagnetic radiations and noises generated in use of the outdoor power supplies as well as pollutions generated in operation of the fossil oil powered power generators all have an adverse effect on people's living environments. Additionally, laying cables from a long distance is difficult and may destroy the surrounding environment, and the additional construction associated with this consumes many labor hours and a high cost.

Accordingly, an urgent need exists in the art to provide a solution that can use a solar energy power generating device in conjunction with a mobile device to overcome the shortcomings associated with the conventional outdoor power supplies or with laying cables from a long distance (e.g., they may generate noises and pollution, and consume additional labor hours and cost).

### BRIEF SUMMARY OF THE INVENTION

In view of the problems and shortcomings of the conventional utility power and outdoor power supplies in use, the applicant of the present application has made repeated experiments and modifications based on intensive evaluations and considerations, and finally provided a mobile solar energy system disclosed herein.

A primary objective of the present invention is to receive a solar energy device in a chamber of a case and dispose a cover at a top opening of the chamber so that, when the sunlight propagates through the cover or impinges directly on solar panels, the solar energy can be transformed by a plurality of solar modules into the electric energy for charging a battery module. Thus, the solar energy device can be loaded inside the chamber of a standard case and then transported by a means of transportation conveniently with improved mobility. On the other hand, the solar energy device can significantly reduce the electromagnetic radiations, noises and pollutant emissions in operation as compared to the conventional outdoor power supplies (e.g., generators); also, this can avoid damage to the environment due to the need of laying cables from a long distance for connection with the utility power, and eliminate the need of additional labor hours and cost associated with laying of the cables.

A secondary objective of the present invention is to have the cover automatically opened or closed by means of a controlling device and have the solar panels driven by a lifting device to above the case and unfolded in a planar form or tilted at a predetermined angle. Thus, a large-area design can be adopted for the solar panels and the driving part can be designed in such a way that the solar panels rotate or move synchronously with the sun just like a sun tracking system. In this way, the light receiving area and the solar energy absorbed can be increased to provide a desirable electric power output efficiency; for example, the overall output power of the solar energy device may be as high as 5 kW or more.

A further objective of the present invention is to have the solar panels of the solar energy device aligned with the cover at the top opening of the chamber. The cover may be a fixed structure and formed of a transparent material. When the sunlight propagates through the cover to the solar panels, the excessive electric energy generated can be stored in the battery module so that power can be supplied uninterruptedly regardless of changes of the weather. Furthermore, when the case is moved to an outdoor environment where a power supply is unavailable (e.g., in case of a power failure, in a stricken area, at a large-scale concert or a mobile performance), the mobile solar energy system will not be affected by the rain, moisture, dust and the like; and this can also provide a desirable anti-theft function and makes the mobile solar energy system endurable.

### BRIEF DESCRIPTION OF THE SEVERAL VIEWS OF THE DRAWINGS

The invention as well as a preferred mode of use and advantages thereof will be best understood by referring to the following detailed description of an illustrative embodiment in conjunction with the accompanying drawings, wherein:

FIG. 1 is a perspective outside view of the present invention;

FIG. 2 is a cross-sectional side view of the present invention;

FIG. 3 is a perspective outside view (I) of the present invention when being used;

FIG. 4 is a perspective outside view (II) of the present invention when being used;

FIG. 5 is a cross-sectional side view of the present invention when being used;

FIG. 6 is a perspective outside view of the present invention after being used;

FIG. 7 is a cross-sectional side view of the present invention after being used;

FIG. 8 is a schematic view illustrating a structure of a preferred embodiment of the present invention; and

FIG. 9 is a perspective outside view of another preferred embodiment of the present invention.

### DETAILED DESCRIPTION OF THE PREFERRED EMBODIMENT

For better understanding of the aforesaid objectives and structures as well as the technical means and efficacies of the present invention, preferred embodiments of the present invention will be detailed with reference to the attached drawings.

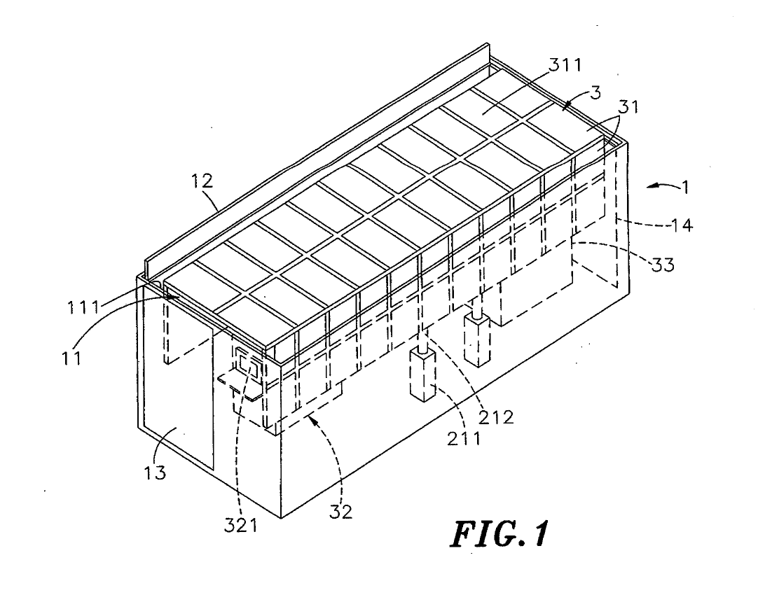

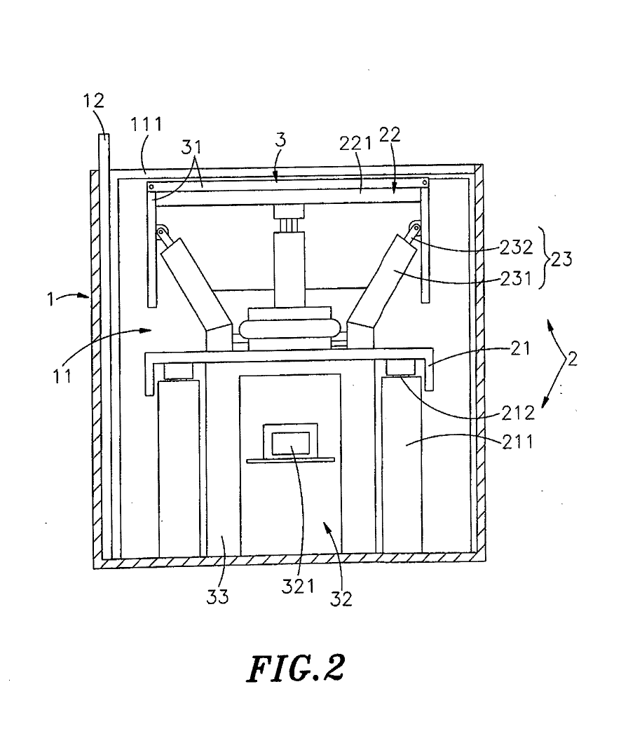

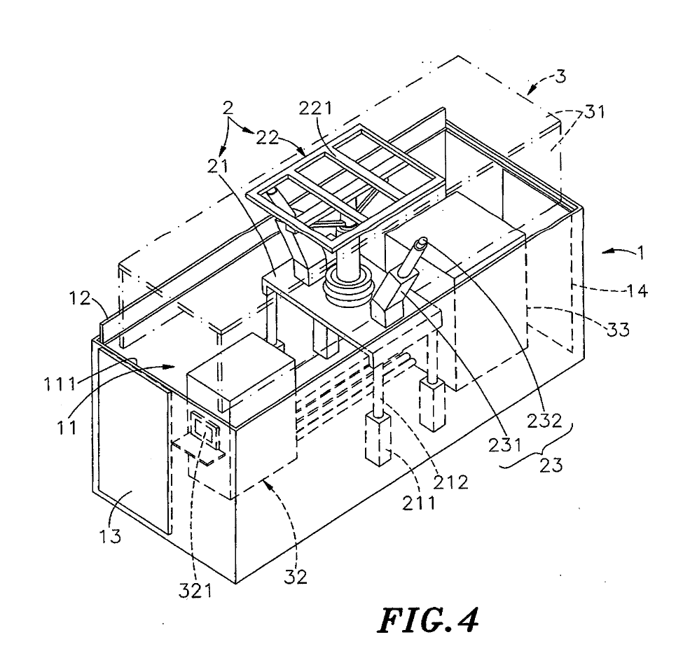

Referring to FIGS. 1, 2, 3, and 4 together, a perspective outside view of the present invention, a cross-sectional side view of the present invention, a perspective outside view (I) of the present invention when being used and a perspective outside view (II) of the present invention when being used are shown therein respectively. As can be seen clearly from these figures, the present invention comprises a case 1, a lifting device 2 and a solar energy device 3.

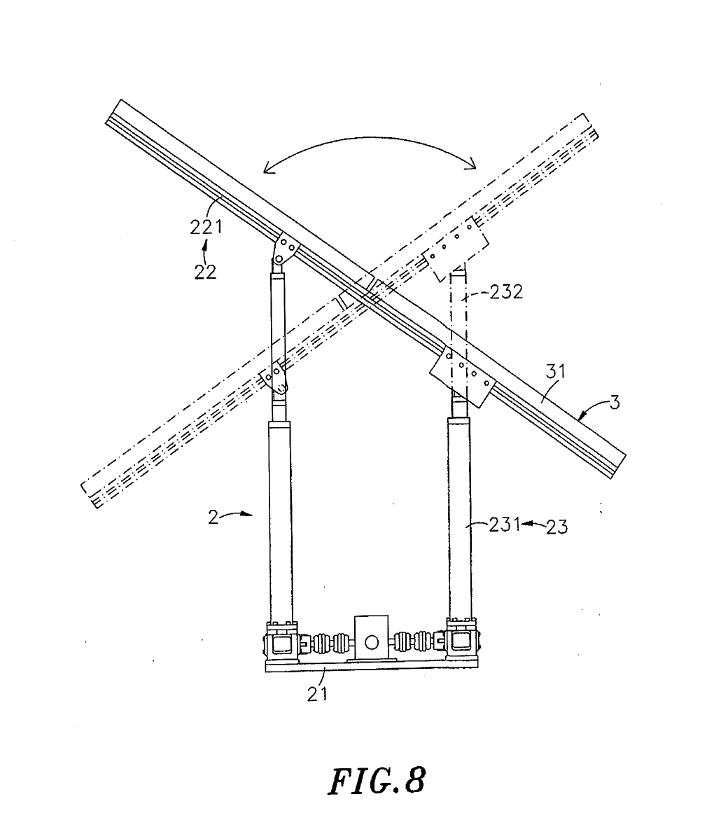

The case 1 may be a container, a car, a ship's cabin or some other case of a rectangular form, a polygonal form or the like used for shipping by vehicles, ships or other means of transportation. A chamber 11 for receiving the lifting device 2 and the solar energy device 3 is formed inside the case 1, and a cover 12 is disposed at a top opening 111 of the chamber 11. The cover 12 may be a fixed or detachable structure, and is formed of a reinforced glass or plastic material that is transparent, translucent or partially transparent. Alternatively, the cover 12 is formed of a same metal material as the case 1 separately, or may be formed of a transparent, translucent or partially transparent reinforced glass or plastic material in combination with a metal material. Furthermore, the cover 12 may be pivoted inside the chamber 11 and is driven by a motor-driven screw, a fluted disc, a belt in combination with a pulley, a chain in combination with a sprocket, a pneumatic cylinder, a cross-link mechanism (as shown in FIG. 8) or the like; or the cover 12 may slide along a slideway into an opened or closed status. Additionally, door panels 13, 14 that can be opened or closed by a user are disposed at a front side and a back side of the case 1 respectively.

The lifting device 2 comprises a supporting base 21, a pedestal 22 and a driving part 23 for driving the pedestal 22 to extend out of the case 1. A plurality of pneumatic cylinders 211 having telescopic links 212 are disposed at bottom corners of the supporting base 21. Thus, the telescopic links 212 of the pneumatic cylinders 211 are connected to the supporting base 21 so that the pneumatic cylinders 211 can drive the supporting base 21 to reciprocate in a vertical direction; alternatively, the supporting base may slide along a slideway.

Furthermore, the pedestal 22 is integrally connected with the supporting base 21 by means of the driving part 23. In this preferred embodiment, the driving part 23 is provided with at least one pneumatic cylinder 231 and the telescopic links 232 of the pneumatic cylinders 231 are connected to a bottom of the pedestal 22 respectively to drive the pedestal 22 to reciprocate in a vertical direction; however, this is only provided as a preferred embodiment but is not an essential feature of the present invention. Specifically, the driving part 23 may also be a motor-driven screw, a fluted disc, a belt in combination with a pulley, a chain in combination with a sprocket, a hydraulic cylinder, a cross-link mechanism (as shown in FIG. 8) or the like, although what described above is simple to assemble and is stable in structure. Also, these structures may be used in combination arbitrarily depending on the practical requirements or design. The pedestal 22 has one or more frames 221 pivoted to each other so that the driving part 23 can be connected to a bottom of the frames 221 of the pedestal 22 by means of the telescopic links 232 of the pneumatic cylinders 231 and drive the frames 221 to move to the top opening 111 of the case 11. Then, the frames 221 are unfolded into a planar form or tilted at a predetermined angle.

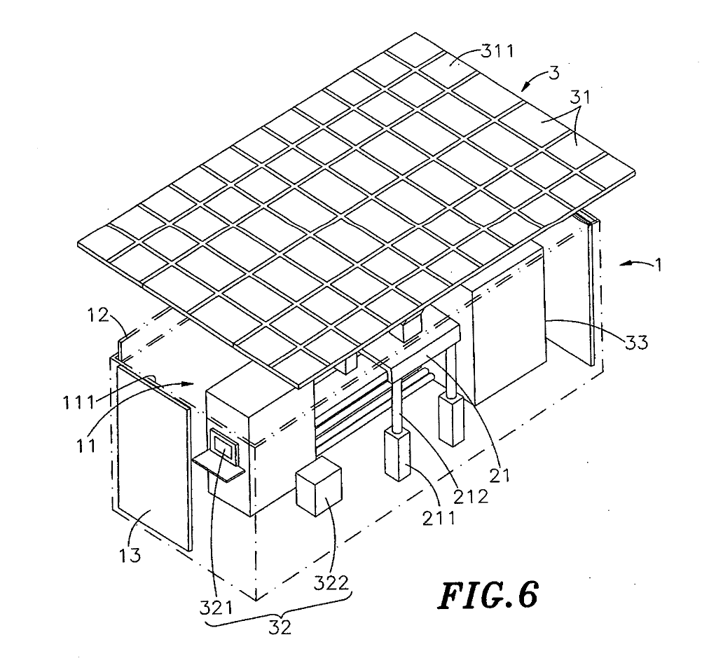

The solar energy device 3 comprises one or more solar panels 31 located on the pedestal 22 of the lifting device 2, and a plurality of solar modules 311 are disposed on the solar panels 31. The solar panels 31 are connected with a battery module 33 that can be electrically connected to a controlling device 32. The controlling device 32, which may be a host 321 of a computer or a host of a controlling system, is disposed at a side of the lifting device 2 to control powering-on, powering-off and setting of related parameters of the lifting device 2 and the battery module 33. The controlling device 32 may also have an uninterruptible power supply (UPS) 322 or a power supply management device built therein or externally connected thereto (as shown in FIG. 6) to control output of the electric power stored in the battery module 33.

The plurality of solar modules 311 of the solar panels 31 may be solar cells, and the solar cells are classified into wafer-based solar cells and thin-film solar cells. The wafer-based (crystalline silicon) solar cells may be monocrystalline silicon, polysilicon or group III-V compound semiconductor wafers, and are each comprised of a solar wafer, a base and a Fresnel curved mirror (not shown). When the incident sunlight rays impinge on the Fresnel curved mirror, the incident sunlight rays are refracted to a reflector disposed on the base and then the refracted sunlight rays are focused by the reflector onto the solar wafers located at the central focusing region of the base, thus achieving the purpose of transforming the solar energy into the electric energy. However, the above description of utilizing a Fresnel curved mirror to refract the sunlight rays to the base and then focusing the sunlight rays onto the solar wafers is only provided as a preferred embodiment but is not an essential feature of the present invention, so no further description will be made thereon.

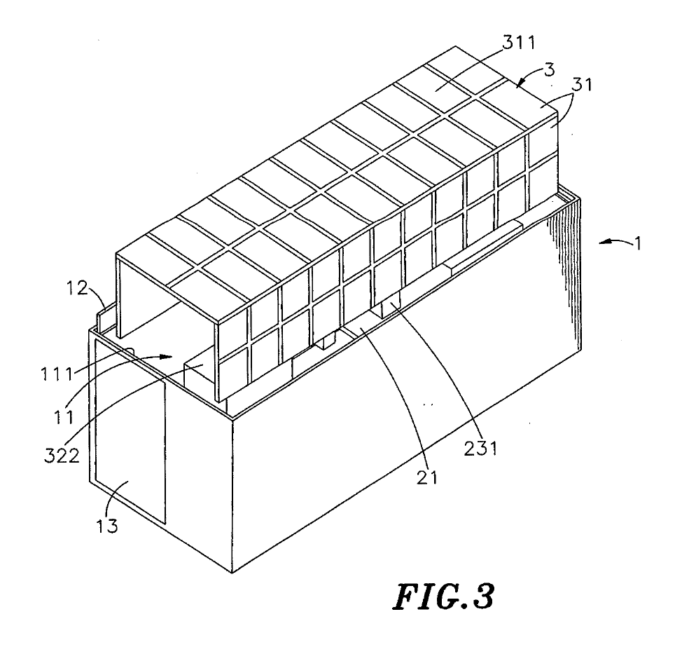

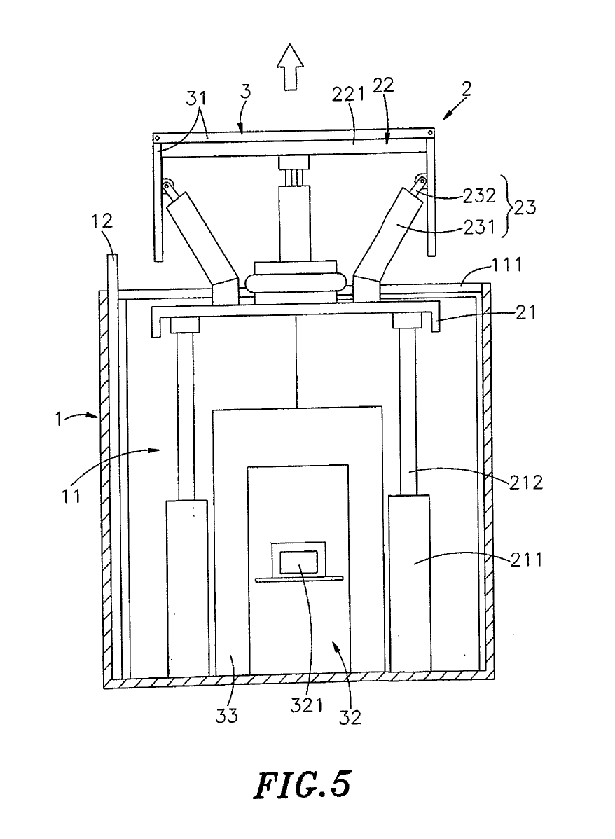

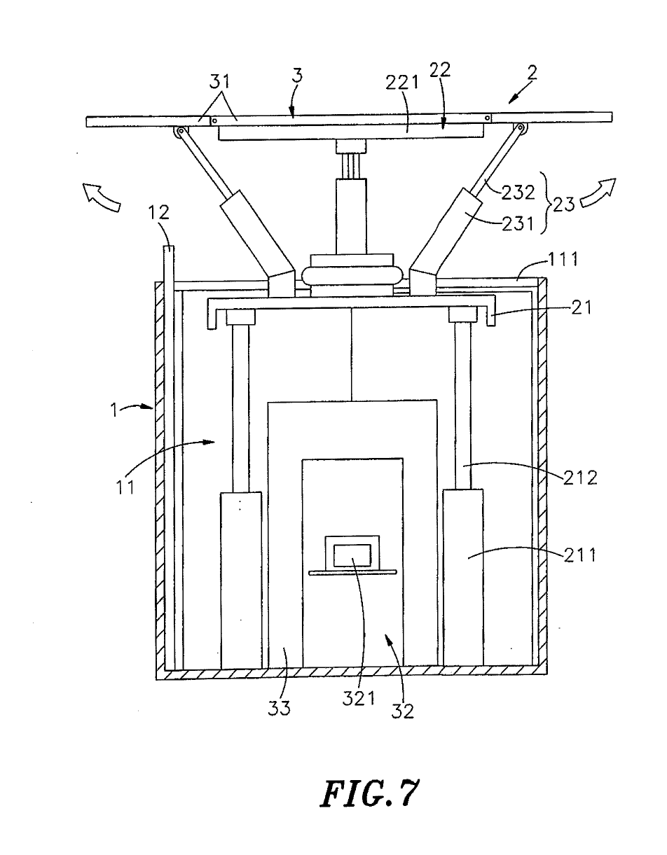

Referring to FIGS. 3, 4, 5, 6, 7 and 8 together, a perspective outside view (I) of the present invention when being used, a perspective outside view (II) of the present invention when being used, a cross-sectional side view of the present invention when being used, a perspective outside view of the present invention after being used, a cross-sectional side view of the present invention after being used and a schematic view illustrating a structure of a preferred embodiment of the present invention are shown therein respectively. As can be seen clearly from these figures, prior to use of the case 1, the cover 12 is closed on the top opening 111 of the chamber 11 with the clearance between the cover 12 and the chamber 11 being completely sealed to surely prevent entry of moisture, dust or other foreign matters. Thus, when the case 1 is located outdoors and exposed to the sunlight, wind or rain, the mobile solar energy system will not be affected by the rains, moisture, dust and the like; furthermore, this can provide a desirable anti-theft function and makes the mobile solar energy system endurable.

During use of the present invention, the controlling device 32 received inside the chamber 11 of the case 1 is firstly used to perform controlling operations or for input of operation instructions so that the host 321 can drive the cover 12 to be automatically opened or closed and then lifting device 2 drives the solar panels 31 on the solar energy device 3 to extend out of the top opening 111 of the case 1. The solar panels 31 are driven by the lifting device 2 in the following way: the supporting base 21 is driven by the plurality of pneumatic cylinders 211 located at bottom corners of the supporting base 21 to reciprocate in the vertical direction, and then through the telescopic links 232 of the pneumatic cylinders 231 of the driving part 23 that are connected to the one or more frames 221 pivoted to each other, the frames 221 and the solar panels 31 located on the frames 221 are moved to the top opening 111 of the case 1; then, the solar panels 31 are unfolded into a planar form or tilted at a predetermined angle in such a way that a total area of the unfolded solar panels 31 is greater than an area of the case 1. Thus, when the sunlight impinges on the solar panels 31 directly, the sunlight will be absorbed and transformed by the solar modules 311 into the electric energy for output to charge the battery module 33. In this way, the excessive electric energy can be stored in the battery module 33 so that there is still sufficient electric power for use on cloudy or rainy days; alternatively, the electric energy may be supplied through a cable directly to an external electric device (not shown). Moreover, the solar energy device 3 allows for unattended operation and can supply power to a load just like a conventional energy source. A large-area design may be adopted for the solar panels 31 and the driving part 23 may be designed as a motor-driven screw, a fluted disc, a belt in combination with a pulley, a chain in combination with a sprocket, a hydraulic cylinder, or a cross-link mechanism (as shown in FIG. 8) so that the solar panels 31 can rotate or move synchronously with the sun just like a sun tracking system. By automatically adjusting the angle at which the sunlight impinges on the solar panels 31, the light receiving area and the solar energy absorbed can be increased to provide a desirable electric power output efficiency; for example, the overall output power of the solar energy device 3 may be as high as 5 kW or more.

Furthermore, when the user desires to move the case 1 to an outdoor environment where a power supply cannot be obtained readily (e.g., in case of a power failure, in a stricken area, at a large-scale concert or a mobile performance), a means of transportation (e.g., a vehicle, a truck, a trailer or a ship) may be used to transport the case 1. This makes it convenient to disassemble and assemble or movably dispose the solar energy device 3 with improved mobility. Thus, the solar energy device 3 can be loaded inside the chamber 11 of a standard case 1 and then transported by a trailer or a ship conveniently. On the other hand, the solar energy device 3 provides a pollution-free and noise-free direct current (DC) power supply, which can significantly reduce the electromagnetic radiations, noises and pollutant emissions and improve the energy utilization factor as compared to fossil oil based power generation conventionally adopted for outdoor power supplies (e.g., generators); also, this can avoid damage to the environment due to the need of laying cables from a long distance for connection with the utility power, the inconvenience, and the additional labor hours and cost associated with laying of the cables. Thereby, the solar energy system has an improved mobility without being affected by the environment, which makes it more competitive in the market.

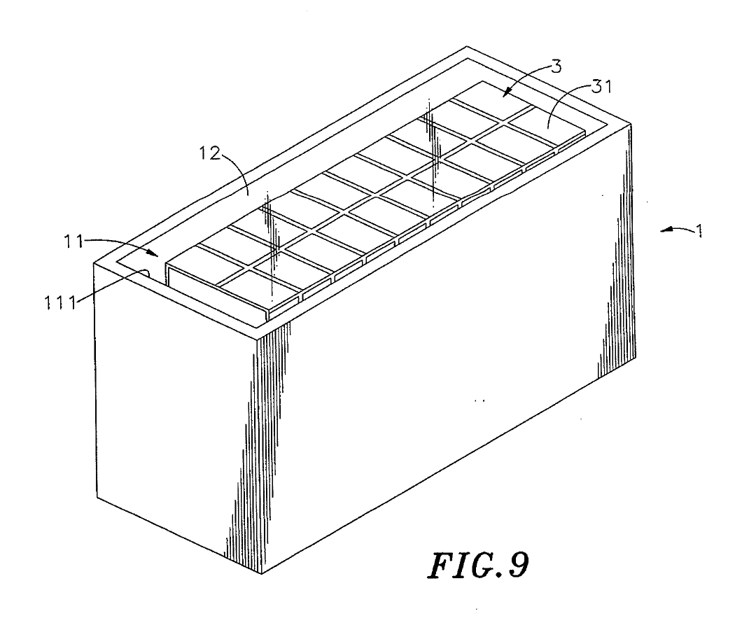

Referring to FIGS. 1, 2, and 9 together, a perspective outside view of the present invention, a cross-sectional side view of the present invention, and a perspective outside view of another embodiment of the present invention are shown therein respectively. As can be seen clearly from these figures, in this preferred embodiment, the lifting device 2 and the solar energy device 3 are received inside the case 1. However, the present invention is not limited thereto in practical application; instead, it is possible that the chamber 11 of the case 1 only has the solar energy device 3 disposed therein in such a way that at least one solar panel 31 of the solar energy device 3 is aligned with the cover 12 located at the top opening 111 of the chamber 11, and the cover 12 may also be a fixed structure and be formed of a reinforced glass or plastic material that is transparent, translucent or partially transparent provided that, when the sunlight propagates through the cover 12 to impinge onto the solar panels 31 directly, the solar energy is transformed into the electric energy by the solar modules 31 and then outputted to charge the battery module 33. Additionally, the excessive electric power may be stored into the battery module 33 on normal days so that power can be supplied uninterruptedly even when the weather changes frequently.

What detailed above is only a preferred embodiment of the present invention. However, this embodiment is not intended to limit the scope of the present invention; rather, any equivalent alterations or modifications that can be made within the technical spirit of this application shall still fall within the scope of this application.

In summary, the solar energy system of the present invention can surely achieve the objectives and efficacies thereof, so it is indeed an invention of great utility. Hence, this application conforms to the elements for an invention in every aspect, and is hereby filed for examination by the Examination Committee. We are looking forward to an early granting approval so that this application will benefit the society, and we will be very appreciated for this.

What the Invention claimed is:

1. A mobile solar energy system, comprising:
a case, in which a chamber for receiving a lifting device and a solar energy device is formed, wherein a cover that can be opened or closed is disposed at a top opening of the chamber;
a lifting device, comprising a supporting base, a pedestal and a driving part for driving the pedestal to extend out of the top opening of the chamber, wherein the pedestal is integrally connected with the supporting base by means of the driving part;
a solar energy device, comprising one or more solar panels located on the pedestal of the lifting device, wherein a plurality of solar modules are disposed on the one or more solar panels, and a battery module electrically connected to a controlling device is connected to the solar panels so that, when the sunlight impinges on the solar panels, the solar energy can be transformed into electric energy by the solar modules and then transmitted to the battery module for charging.

2. The mobile solar energy system in claim 1, wherein the case is selected from the group of a container, a car and a ship's cabin used in transportation.

3. The mobile solar energy system in claim 1, wherein the cover of the case is a fixed or detachable structure, and is made of a material selected from the group of a reinforced glass and a reinforced plastic material that is transparent, translucent or partially transparent.

4. The mobile solar energy system in claim 1, wherein the cover of the case is a fixed or detachable structure, and the cover is formed of a metal material separately or is formed of one of a transparent, translucent or partially transparent reinforced glass and a transparent, translucent or partially transparent reinforced plastic material in combination with a metal material.

5. The mobile solar energy system in claim 1, wherein the cover of the case may be pivoted inside the chamber and is provided with door panels that can be movably opened or closed by a user on a front side and a back side of the case respectively.

6. The mobile solar energy system in claim 1, wherein a plurality of pneumatic cylinders are disposed at bottom corners of the supporting base of the lifting device, and are connected to the supporting base by means of telescopic links of the pneumatic cylinders respectively so that the pneumatic cylinders can drive the supporting base to reciprocate in a vertical direction.

7. The mobile solar energy system in claim 1, wherein the driving part of the lifting device is selected from the group of a motor-driven screw, a belt in combination with a pulley, a chain in combination with a sprocket, a pneumatic cylinder, a hydraulic cylinder, and a cross-link mechanism, the pedestal comprises one or more frames pivoted to each other, and the solar panels of the solar energy device are located on the frames and are connected to a bottom of the frames by means of the driving part so that the frames are driven to above the case and the solar panels are unfolded into a planar form or tilted by a predetermined angle, wherein a total area of the unfolded solar panels is greater than an area of the case.

8. The mobile solar energy system in claim 1, wherein the solar modules on the solar panels of the solar energy device are selected from the group of wafer-based solar cells and thin-film solar cells, and the wafer-based solar cells are selected from the group of monocrystalline silicon, polycrystalline silicon and group III-V compound semiconductor wafers.

9. The mobile solar energy system in claim 1, wherein the controlling device of the solar energy device is disposed at a side of the lifting device and is selected from the group of a host of a computer and a host of a control system, powering on, powering off and setting of related parameters of the lifting device and the battery module are controlled by the control device, and the controlling device has one of an uninterruptible power supply (UPS) and a power supply management device built therein or externally connected thereto.

10. A mobile solar energy system, comprising a case and a solar energy device, wherein a chamber inside the case is adapted to receive the solar energy device, a cover is disposed above the chamber, the solar energy device comprises one or more solar panels aligned with the cover, a plurality of solar modules are disposed on the one or more solar panels, and a battery module electrically connected to a controlling device is connected to the solar panels so that, when the sunlight propagates through the cover onto the solar panels directly, the solar energy can be transformed into electric energy by the solar modules and then transmitted to the battery module for charging.

11. The mobile solar energy system in claim 10, wherein the case is selected from the group of a container, a car and a ship's cabin used in transportation.

12. The mobile solar energy system in claim 10, wherein the cover of the case is a fixed or detachable structure, is pivoted inside the chamber and is provided with door panels that can be movably opened or closed by a user on a front side and a back side of the case respectively.

13. The mobile solar energy system in claim 10, wherein the solar modules on the solar panels of the solar energy device are selected from the group of wafer-based solar cells and thin-film solar cells, and the wafer-based solar cells are selected from the group of monocrystalline silicon solar cells and polycrystalline silicon solar cells.

14. The mobile solar energy system in claim 10, wherein the controlling device of the solar energy device is disposed at a side of the lifting device and is selected from a host of a computer and a host of a control system, powering on, powering off and setting of related parameters of the lifting device and the battery module are controlled by the control device, and the controlling device has one of an uninterruptible power supply (UPS) and a power supply management device built therein or externally connected thereto.
